(19) United States
(12) Patent Application Publication
(10) Pub. No.: US 2010/0053882 A1
(43) Pub. Date: Mar. 4, 2010

(54) Panel Detaching Mechanism

(76) Inventor: Shun Hayashi, Gunma-ken (JP)

Correspondence Address: CARR & FERRELL LLP, 2200 GENG ROAD, PALO ALTO, CA, 94303, US

(21) Appl. No.: 12/534,136

(22) Filed: Aug. 2, 2009

(30) Foreign Application Priority Data
Aug. 26, 2008 (JP) JP2008-217127

(51) Int. Cl. H05K 7/16

(52) U.S. Cl. 361/679.43

(57) ABSTRACT

In a car audio system, a hook part and a projection latches an operation panel with a front bracket and releases the latching of the operation panel when a user operates a lever. A tilt mechanism pulls out the front bracket so that the lower outer edge of the operation panel is pulled out from the state where the operation panel is latched at a standard position with the operation panel latched. The lever is arranged near the panel back face so that the lever cannot be operated by a user when the panel is latched by the front bracket at the standard position, but can be operated by a user when the front bracket is pulled out with the operation panel latched.

### CROSS-REFERENCE TO RELATED APPLICATIONS

The present application claims the priority benefit of Japanese patent application number 2008-217127 filed Aug. 26, 2008, the disclosure of which is incorporated herein by reference.

### BACKGROUND OF THE INVENTION

1.Field of the Invention

The present invention generally relates to a panel detaching mechanism. More specifically, the present invention relates to a panel detaching mechanism whereby a panel is detached from a main body.

2. Description of the Related Art

Car audio systems or car navigation systems are widely mounted in vehicles. Many of these systems are expensive and there is a fear of theft during absence of a car occupant. An electronic device with an operation panel with a lock where the main body can be released by pressing a release key provided on the front face of the panel seeks to address this concern as is evidenced by Japanese patent application publication number H06-239182.

A panel detaching mechanism whereby a latching with the main body of a system is released by pressing a lock release button provided on the front face of the system thus allowing the panel to be detached from the main body of the system has also seeks to address the aforementioned concern as evidenced by Japanese patent application publication number H10-230796.

Japanese patent application publication number H11-273323 has the purpose of preventing that an operating member sticks to the main body so that it cannot be taken out, an operation device for an electronic apparatus is proposed in which a rotating body is over rotated by a further push operation of a release button by which a tapered face of the operating member is directly pressed.

In many cases, a display or operation buttons are arranged on the front face of a panel. Arranging a button for detaching a panel on the front face of the panel occupies part of the front face, which reduces space for arranging a display or operation buttons.

### SUMMARY OF THE INVENTION

The present invention simplifies the structure of the front face of a panel and provides a panel detaching mechanism that can suitably detach a panel from the main body.

A panel detaching mechanism according to an embodiment of the present invention comprises: an operating member adapted to be operated by a user and a latch mechanism adapted to latch the panel with a main body, the latch mechanism releasing the latching when a user operates the operating member. The operating member is arranged near the panel back face in the state where the panel is latched with the main body.

### BRIEF DESCRIPTION OF THE DRAWINGS

FIG. 1 is a perspective view of a car audio system according to an embodiment of the present invention.

FIG. 2 is a perspective view of the car audio system according to the present embodiment where the operation panel is pulled out.

FIG. 3 is a perspective view of the car audio system according to the present embodiment where the operation panel is completely detached.

FIG. 4 is a front view of the operation panel according to the present embodiment.

FIG. 5 is a bottom view of the operation panel according to the present embodiment.

FIG. 6A is a side view of the car audio system according to the present embodiment before the operation panel is detached.

FIG. 6B is a side view of the car audio system according to the present invention after the operation panel has been detached.

FIG. 7 is a back view of the operation panel according to the present embodiment.

FIG. 8 is a front view of a support unit according to the present embodiment.

FIG. 9 is a perspective view of a stopper according to the present embodiment.

FIG. 10 is a perspective view of the support unit from behind in accordance with the present embodiment.

FIG. 11A illustrates the operation panel latched with the support unit at a basic position.

FIG. 11B illustrates the support unit pulled out by a tilt mechanism with the operation panel latched.

FIG. 11C illustrates a lever operated from the state of FIG. 11B.

FIG. 12A illustrates the operation panel latched with the support unit.

FIG. 12B illustrates the operation panel from the state of FIG. 12A after operation of the lever.

FIG. 12C illustrates the panel top face pressed from the state of FIG. 12(B).

FIG. 12D illustrates the operation panel having been pulled out to the front and upwards of the system from the state of FIG. 12C.

### DETAILED DESCRIPTION

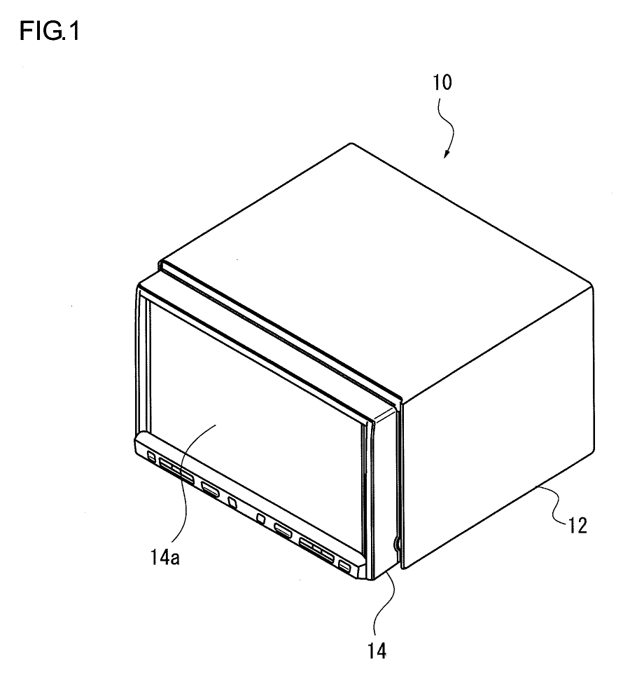

FIG. 1 is a perspective view of car audio system 10 according to an embodiment. The car audio system 10 is an audio system mounted on the instrument panel or the like of a vehicle and includes a main body 12 and operation panel 14.

The main body 12 has a rectangular parallelepiped shape, the whole of which is housed in an instrument panel of a vehicle when mounted thereon. The operation panel 14 has substantially the same width and height as those of the main body 12 and a shorter depth than that of the main body 12.

The operation panel 14 is equipped in front of the main body 12. When the car audio system 10 is mounted on a vehicle, the system is arranged on the front face of the instrument panel of a vehicle in the state of being exposed outwards so that the panel front face 14a can be seen by an occupant of a vehicle. The operation panel 14 is latched with the main body 12 at the standard position where the panel front face 14a is perpendicular to the car audio system when the car audio system is put on a horizontal plane-the usual state where the operation panel 14 is not pulled out.

A car navigation system may alternatively be adopted instead of a car audio system. The audio system may be a home audio system without being limited to a car audio system.

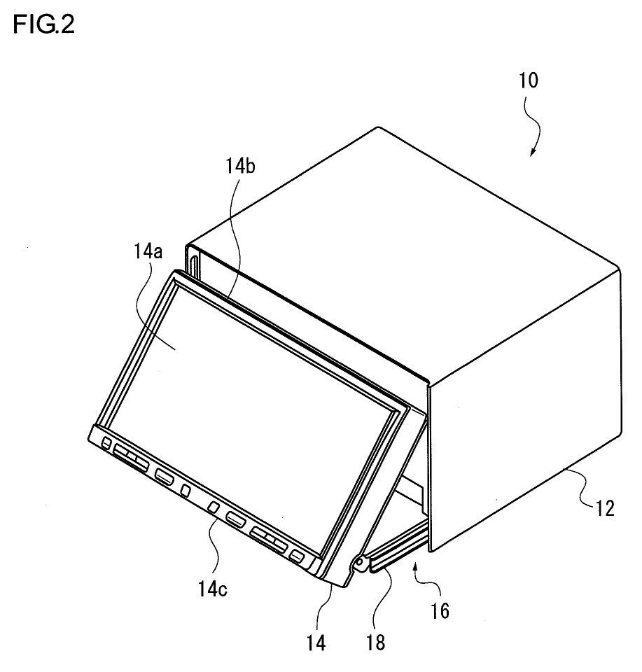

FIG. 2 is a perspective view of the car audio system 10 according to the present embodiment where the operation panel 14 is pulled out. The car audio system 10 is provided with a support unit (not illustrated) and a tilt mechanism 16. The operation panel 14 is latched with the support unit. The panel top face 14b and the panel bottom face 14c are parts of the outside edges (outside faces) in contact with the panel front face 14a. The tilt mechanism 16 functions so that the panel bottom face 14c can be pulled out more than other outside faces such as the panel top face 14b with the operation panel 14 latched with the support unit and where the operation panel 14 is in the standard position by pulling out the support unit.

Specifically, the tilt mechanism 16 includes a motor (not illustrated) that is an electric actuator, a rack gear mechanism (not illustrated), and two rods 18. A tilt button (not illustrated) is provided on the panel front face 14a. When a user presses the tilt button, the motor is operated by a control unit (not illustrated), which comprises a microcomputer provided within the main body 12, or the like, so that the rods 18 respectively extend out from the right and left lower parts of the front face of the main body 12 through the rack gear mechanism. The tips of the two rods 18 are pivoted on the lower parts of the support units. As the rods 18 move forward, the panel bottom face 14c moves forward and the panel top face 14b moves downwards with the whole operation panel 14 being tilted diagonally. The motor has a breaking mechanism and the operation panel 14 is configured so as not to be pulled out manually from outside but to be pulled out from the basic position only by activating the motor.

Since car audio systems are generally expensive, there is a fear of theft during absence of car occupant if the car audio system is left in the vehicle. The car audio system 10 of the present embodiment is provided so that the operation panel 14 is detachable from the main body 12.

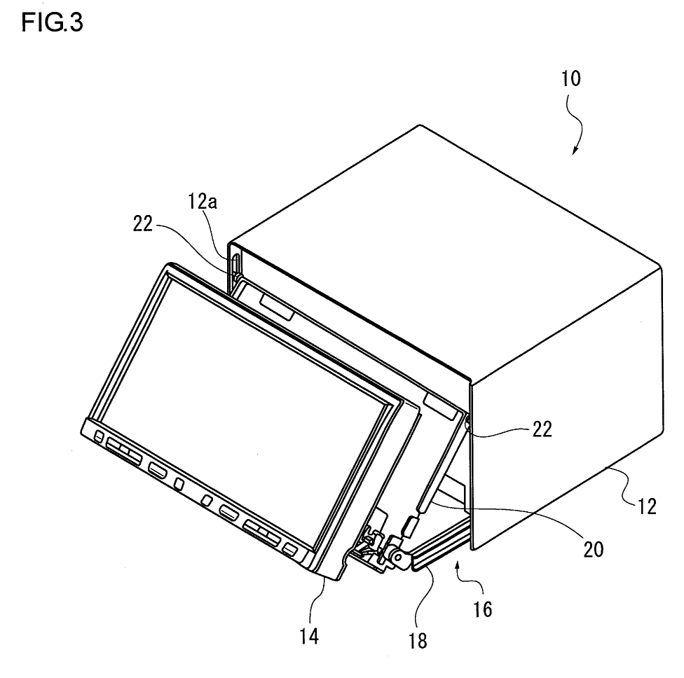

FIG. 3 is a perspective view of the car audio system according to the present embodiment where the operation panel 14 is detached. The operation panel 14 is provided to be detachable to the support unit 20 that latches the operation panel 14 covering the back face of the operation panel 14. In the car audio system 10 of the present embodiment, the operation panel 14 can be attached to and detached from, respectively, the support unit 20 where the operation panel 14 is at the standard position or is pulled out by the tilt mechanism 16.

Guide shafts 22 are secured both on the upper part of the right side and on the upper part of the left side of the support unit 20. Each of the guide shafts 22 is inserted through a guide part 12a—a long hole extending in the vertical direction, which is provided in the lateral front part of the main body 12. This allows the panel top face 14b to move downwards smoothly when the panel bottom face 14c is pulled out by the tilt mechanism 16.

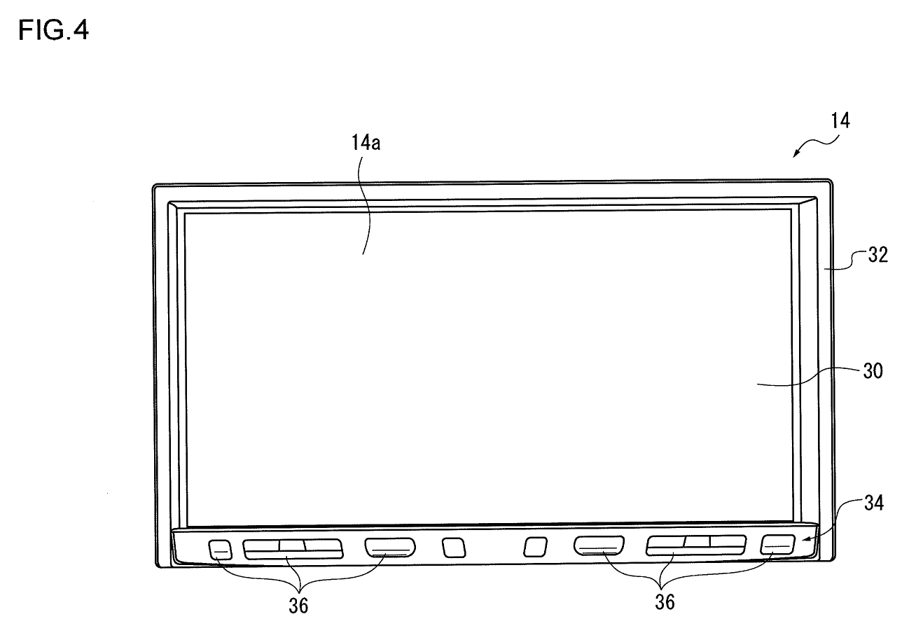

FIG. 4 is a front view of the operation panel 14 according to the present embodiment. The panel front face 14a is provided with a display 30 and a control panel 34. The display 30 has a screen slightly smaller than the size of the panel front face 14a. A frame-shaped front cover 32 is provided on the outer edge of the display 30. The control panel 34 includes a plurality of operation buttons 36, which are arranged in the lower front face of the front cover 32.

The display 30 may alternatively be a touch panel. A display may be solely provided on the panel front face 14a without a control panel. This can lead to increase the size of display. A control panel may instead be provided solely on the panel front face 14a without a display.

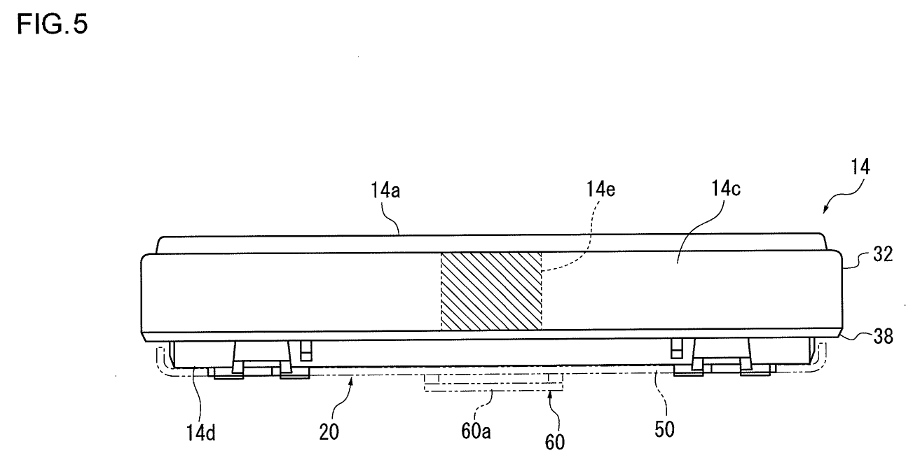

FIG. 5 is a bottom view of the operation panel 14 according to the present embodiment. The opening of the front cover 32 on the rear side of the system is covered with a rear cover 38. Each of the outside faces in contact with the panel front face 14a is formed with the outside face of the front cover 32.

The support unit 20 includes a latch member 60 that latches the operation panel 14 with the front bracket 50. The latch member 60 includes a lever 60a operable by a user. The lever 60a is arranged so as to be spaced a minute distance apart from the panel back face 14d. The lever 60a is biased by a spring, described herein, in the direction of being spaced from the panel back face 14d and is configured so as to be pivotal in the direction of approaching the panel back face 14d. On the panel bottom face 14c, a holding part 14e is provided between the lever 60 and the panel front face 14a where a user can hold the operation panel 14.

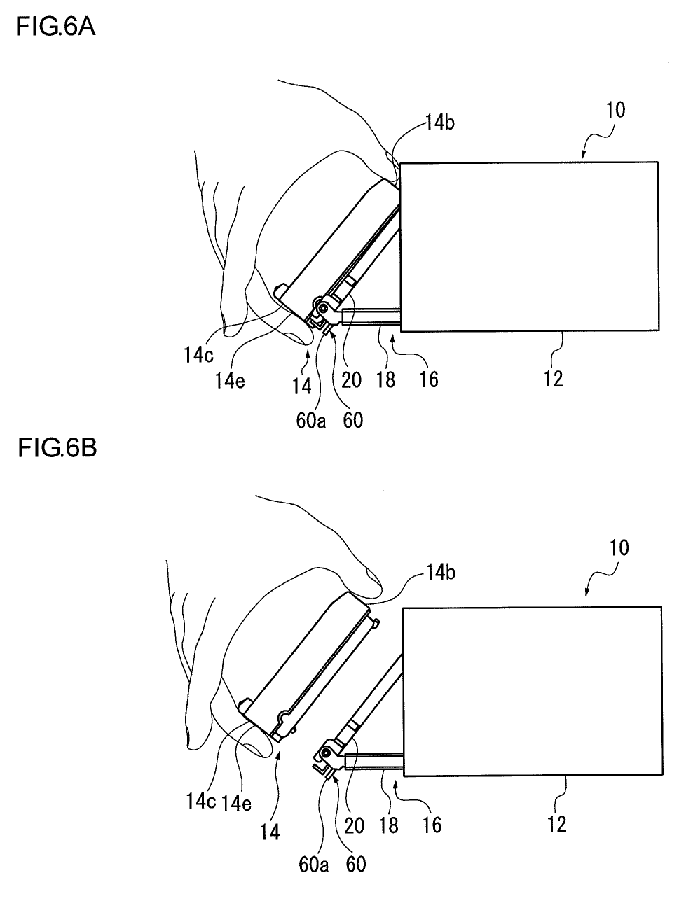

FIG. 6A is a side view of the car audio system 10 according to the present embodiment and before the operation panel 14 is detached. The lever 60a is arranged near the panel bottom face 14c, a longitudinal outer edge portion of the operation panel that is pulled out to the near side by the tilt mechanism 16. The lever 60a is arranged at a position where a user cannot access and operate the lever when the operation panel 14 is latched with the support unit 20 at the standard position. A space is made in the lower part, however, when the support unit 20 is pulled out by the tilt mechanism 16 with the operation panel 14 latched thereby allowing the user to operate the lever 60a.

The car audio system 10 according to the present embodiment is suitable for the 2DIN (Deutsche Industrie Normen) and the operation panel 14 is formed so as to have a height of about 100 mm and a width of about 178 mm. Because the distance between the panel top face 14b and the panel bottom face 14c is small, this allows a user to hold the operation panel 14 with one hand by placing his/her thumb on the panel top face 14b and middle finger or the like on the panel bottom face 14c as illustrated in FIG. 6A. The lever 60a can be operated by the tip of the finger placed on the holding part 14e with the operation panel 14 firmly held. This allows the user to detach the operation panel 14 from the support unit 20 in a stable state.

In addition, a sensor detecting that the operation panel 14 is detached from the support unit 20 may also be provided. The control unit stated above may return the support unit 20 to the standard position by reversing the motor of the tilt mechanism 16 when the detachment of the operation panel 14 is detected. Alternatively, the control unit stated above may turn off the power source of the car audio system 10 after returning the support unit 20 to the standard position by reversing the tilt mechanism 16 when detecting a command to turn off the power source of the car audio system 10 at, for example, the time of turning off the ignition switch of a vehicle.

FIG. 6B is a side view of the car audio system according to the present invention after the operation panel 14 has been detached. As seen above, a user can completely detach the operation panel 14 from the support unit 20 while holding the operation panel 14 with one hand.

Car audio system 10 is not limited to an audio system suitable for the 2DIN. Most persons can hold the panel with one hand when the distance between the opposing outside faces of the panel is 130 mm or less. Accordingly, the car audio system 10 may have two opposing outside faces between which the distance is 130 mm or less, which is the distance one can hold the system with one hand, and the lever 60a may be arranged near one of the two outside faces.

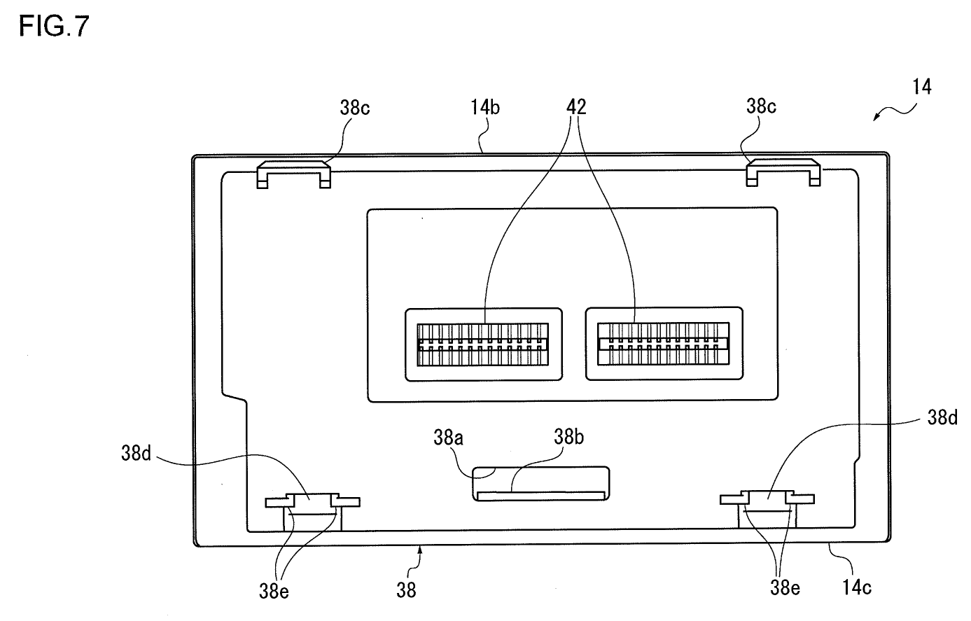

FIG. 7 is a back view of the operation panel 14 according to the present embodiment. The following description assumes that the outside face of a rear cover 38 corresponding to the back face of the operation panel 14 is the front face. A first concave portion 38a is provided in the lower center part of the front face of the rear cover 38. The first concave portion 38a has a horizontally-long rectangular shape and is concaved into the operation panel 14. Projections 38b are provided within the first concave portion 38a. Projections 38b extend upwards from the lower inner face of the first concave portion 38a.

The operation panel 14 is latched with the front bracket 50 by engaging a hook part of the latch member 60 (described later) with the projection 38b. The hook part is lifted by operating the lever 60a thereby allowing the engagement with the projection 38b to be released. The operation panel 14 is provided with a switch (not illustrated) that is turned on when the hook part engaging with the projection 38b is lifted. When turning on, the switch blocks conduction of all terminals in the male connector 42. With this, the male connector 42 can be removed from a female connector (described later) in a state where the conduction is blocked.

Engagement projections 38c project upwards and are provided in each of the right and the left upper parts of the rear cover 38. In addition, second concave portions 38d that are concaved toward the inside of the operation panel 14 are provided in each of the right and the left lower parts of the front face of the rear cover 38. A projection 38e projecting downwards from the upper interior face of the second concave portion 38d is provided within each of the second concave portions 38d.

Two male connectors 42 are arranged horizontally side-by-side at the center on the front face of the rear cover 38. Each of the male connectors 42 has a projection extending horizontally and a plurality of terminals is arranged horizontally and positioned side-by-side on the surface of the projection.

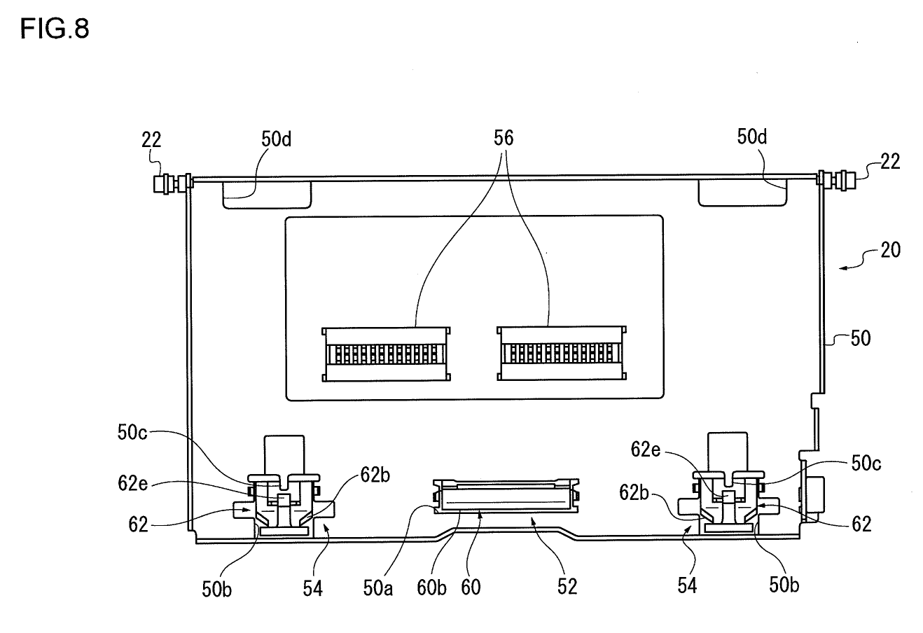

FIG. 8 is a front view of the support unit 20 according to the present embodiment. The support unit 20 has a front bracket 50, a lock unit 52, a stopper unit 54, and a female connector 56. The front bracket 50 is formed by sheet metal processing into a rectangular shape that is horizontally-long with a bent part on its perimeter. The front bracket 50 is arranged so that the bent part extends to the front direction of the system. The front bracket 50 supports the operation panel 14 in a detachable manner. Accordingly, the front bracket 50 functions as a support member for the operation panel 14. The following description assumes that the outside face of the front bracket 50, which corresponds to the front face of the main body 12, is the front face of the front bracket 50.

The lock unit has a latch member 60. The latch member 60 has a hook part 60b projecting downwards. A first opening 50a, which has a horizontally-long rectangular shape, is provided in the lower center of the front bracket 50. The latch member 60 is inserted into the first opening 50a from the back face side of the front bracket 50, and is arranged so that the hook part 60b projects from the front face of the front bracket 50.

The hook part 60b latches the operation panel 14 with the main body 12 by being inserted into the first concave portion 38a provided on the rear cover 38 and by engaging with the projection 38b. The lock unit 52, including the latch member 60, and the projection 38b both accordingly function as a latch mechanism. On the other hand, when a user operates the lever 60a in the state where the operation panel 14 is latched with the main body 12, the hook part 60b is pushed upwards. The latching between the hook part 60a and the projection 38b is then released.

Two latching holes 50d are provided in the right and left upper parts of the front bracket 50, respectively. When the engagement projection 38c provided on the rear cover 38 latches with the engagement hole 50d and the latch member 60 latches with the projection 38b, the operation panel 14 is latched with the main body 12. The engagement hole 50d and the engagement projection 38c also function as a latch mechanism.

When the operation panel 14 is detached from the main body 12 by releasing the latching between the hook part 60b and the projection 38b, the engagement hole 50d and the engagement projection 38c guide the operation panel 14 so that they turn around the latching point between them. The engagement hole 50d and the engagement projection 38c accordingly function as a detachment guide mechanism adapted to guide the operation panel 14 when the latching between the hook part 60b and the projection 38e is released.

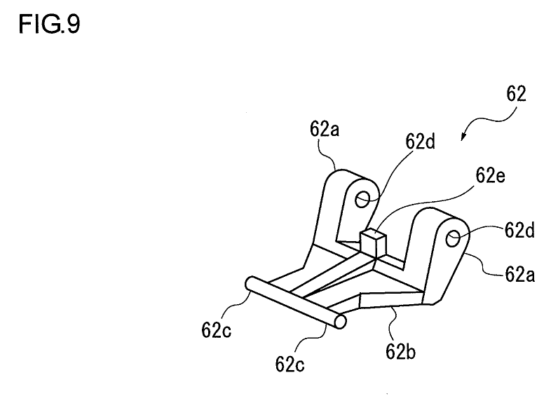

The stopper unit 54 has a stopper 62. The description about the shape of the stopper 62 will be made with reference to FIG. 9.

FIG. 9 is a perspective view of the stopper 62 according to the present embodiment. The stopper 62 is formed into an L-shaped flat panel in which two shaft support parts 62a and a push-out part 62b formed into a plate shape are integrally connected together at their ends. A pair of latching rods 62c is formed at the tip of the push-out part 62b. The pair of latching rods 62c horizontally project in both directions from the push-out part 62b. Two shaft insertion holes 62d, which penetrate coaxially, are provided in the two shaft support parts 62a. The stopper 62 is pivoted on the front bracket 50 by inserting a shaft (described herein) through the shaft insertion holes 62d. A projection 62e is formed between the two shaft support parts 62a. The projection 62e projects upwards from the push-out part 62b.

Referring back to FIG. 8, two second openings 50b are provided in the right and left lower parts of the front bracket 50, respectively. The stopper 62 is arranged so that the push-out part 62b projects from the front face of the front bracket 50. The stopper 62 is pivoted on the front bracket 50. The projection 50c limits the turn of the stopper 62 by contacting with the projection 62e.

The stopper 62 limits the turn of the operation panel 14 around the latching point between the engagement hole 50d and the engagement projection 38c by engaging with the projection 38e provided in the rear cover 38. The stopper unit 54 and the projection 38e accordingly function as a detachment limiting mechanism adapted to limit the movement of the operation panel 14 within a predetermined range of the guide direction when the latching between the latch member 60 and the projection 38b is released. The panel detaching mechanism that detaches the operation panel 14 from the main body 12 comprises the latch mechanism, the detachment guide mechanism, and the detachment limiting mechanism (mentioned above), or the like.

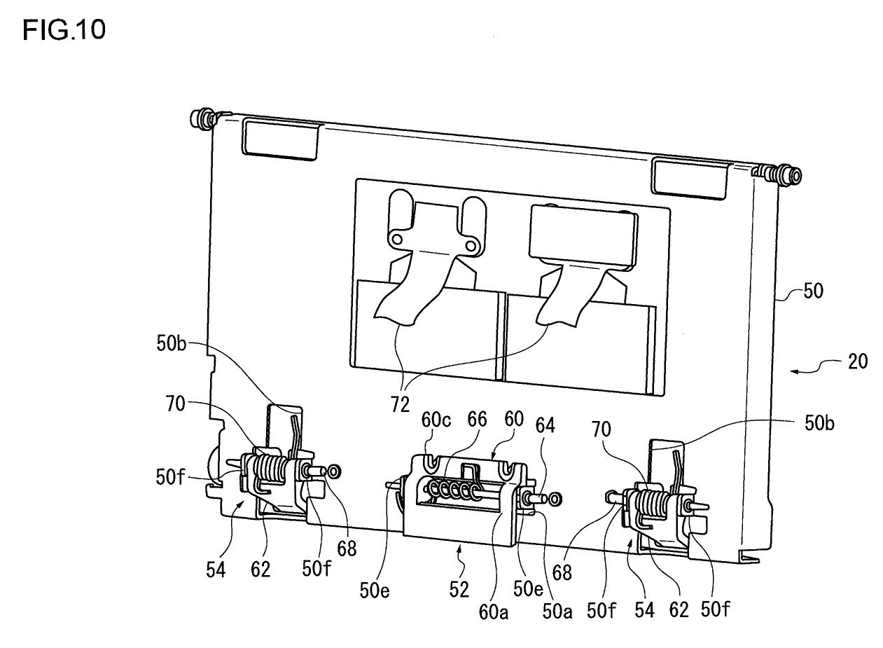

FIG. 10 is a perspective view of the support unit 20 from behind, according to the present embodiment. The lock unit 52 further has a shaft 64 and a coil spring 66. The front bracket 50 is provided with first bent parts 50e, which project from the back face of the bracket at each end of the first opening part 50a. The latch member 60 is arranged between a pair of the first bent parts 50e and pivoted on the front bracket 50 by the shaft 64. At the time, the shaft 64 is inserted through the center of the coil spring 66. The coil spring 66 provides a biasing force in the direction of the turn by which the hook part 60b moves downwards to the latch member 60. At the time, the latch member 60 is latched with a rotating stopper 60c projecting upwards in the latch member 60 engaged with the back face of the front bracket 50.

The stopper unit 54 further has a shaft 68 and a spring 70. A pair of second bent parts 50f are provided with the front bracket 50. The pair of second bent parts 50f project towards the back face of the bracket at each end of the second openings 50b. The stopper 62 is arranged between the pair of the second bent parts 50f and pivoted on the front bracket 50 by the shaft 68. The spring 70 provides a biasing force in the direction of the turn by which the tip of the push-out part 62b moves upwards to the stopper 62.

As illustrated in FIG. 10, the lock unit 52 and the two stopper units 54 are arranged so that they are positioned on a virtual straight line parallel with the bottom face of the front bracket 50, in the vicinity of the bottom face of the front bracket 50 that is pulled out by the tilt mechanism 16. This limits the area where the lock unit 52 and the stopper units 54 are arranged, and allows an area in the front face of the main body 12 which is exposed when the operation panel 14 is pulled out by the tilt mechanism 16, or the like, to be used effectively. In the present embodiment, an insertion slot (not illustrated) for both CD (Compact Disc) and DVD (Digital Versatile Disc) and an insertion slot (not illustrated) for memory cards are provided on the front face of the main body 12 which is exposed when the operation panel 14 is pulled out by the tilt mechanism 16. It is noted that the lock unit 52 and the two stopper units 54 may be arranged in other positions near the bottom face of the front bracket 50, located under the center of the operation panel 14, without being limited to the above position.

Two flat cables 72 are provided that correspond to each of the two female connectors 56. Since the terminals of the female connectors 56 are provided horizontally and positioned side-by-side, each of the flat cables 72 is formed into a plate shape so as to be easily curved around a horizontally-extended axis. This configuration allows the flat cable 72 to be curved easily when the lower part of the support unit 20 is tilted and pulled out by the tilt mechanism 16.

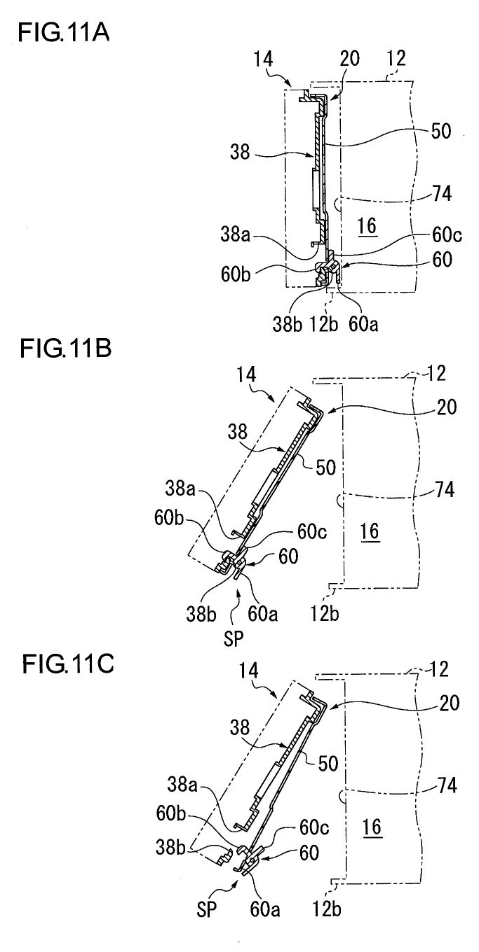

Hereinafter, procedures for detaching the operation panel 14 from the support unit 20 will be described with reference to FIGS. 11(A) to 11(C). It is noted that the outline of the operation panel 14 is illustrated by a two-dot chain line to simplify understanding. In addition, FIGS. 11(A) to 11(C) illustrate cross sectional views in which the operation panel 14 and the support unit 20 are cut face-wise by passing through the center of the latch member 60.

FIG. 11(A) is a diagram illustrating the state where the operation panel 14 is latched with the support unit 20 at a basic position. As illustrated in FIG. 11(A), when the operation panel 14 is at the basic position, the panel back face 14d faces an inner cover 74 that is exposed to the front face of the main body 12 and spaced a small clearance apart from each other when the support unit 20 is pulled out. The lever 60a is arranged within the clearance between the front bracket 50 and the inner cover 74. Almost the whole area of an opening in the lower part of the clearance is covered with a lower cover 12b. The inner cover 74 and the lower cover 12b accordingly function as operation limiting means by which operation of the lever 60a by a user is limited when the operation panel 14 is latched at the basic position.

FIG. 11(B) is a drawing illustrating the state where the support unit is pulled out by the tilt mechanism 16, while the operation panel 14 is being latched. It is noted that the tilt mechanism 16 is not illustrated in FIG. 11(B) in order to simplify the drawings. As illustrated in FIG. 11(B), when the support unit 20 is pulled out by the tilt mechanism 16, a space (clearance) SP is made in the lower part. This allows a user to operate the lever 60a.

FIG. 11(C) is a drawing illustrating the state where the lever 60a is operated from the state of FIG. 11(B). When the lever 60a is pulled out to the near side, the latch member 60 pivots on the rotation axis to lift the hook part 60b. This allows the latching between the hook part 60b and the projection 38b to be released. In this way, the operation panel 14 is detached from the support unit 20.

As stated above, the lever 60a is arranged near the panel back face 14d so that the lever cannot be operated by a user because the lever is close to the inner cover 74 when the front bracket 50 is at the standard position, but can be operated by a user when the front bracket 50 is pulled out. An erroneous operation of the lever 60a can be prevented by structuring the lever 60a so as not to be operated by a user when the support unit 20 is at the standard position.

In addition, the lever 60a is arranged near the panel bottom face 14c that is pulled out to the nearer side than any other part of the panel by the tilt mechanism 16. The lever 60a can be pulled out to the nearer side, allowing a user to easily operate the same.

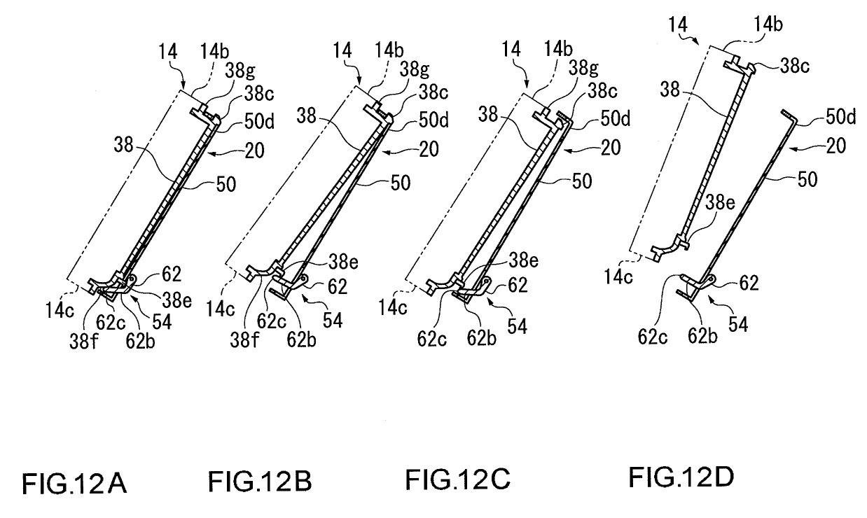

Procedures for detaching the operation panel 14 from the support unit 20 will be described below with reference to FIGS. 12(A) to 12(D). It is noted that the outline of the operation panel 14 is illustrated by a two-dot chain line to simplify understanding. In addition, FIGS. 12(A) to 12(D) illustrate cross sectional views in which the operation panel 14 and the support unit 20 are cut face-wise by passing through the engagement projection 38c and the stopper 62.

FIG. 12(A) is a drawing illustrating the state where the operation panel 14 is latched with the support unit 20. In the lower part of the rear cover 38, an inclined part 38f is formed that inclines so as to draw itself nearer to the front of the system as it approaches the panel bottom face 14c. The tip of the stopper 62 contacts the inclined part 38f. The stopper 62 is provided with a biasing force by the spring 70 by which the tip thereof pushes out the inclined part 38f.

FIG. 12(B) is a drawing illustrating the state immediately after the lever 60a was operated from the state of FIG. 12(A). When the lever 60a is operated by a user so that the latching between the hook part 60b and the projection 38b is released, the stopper 62 pushes out the lower part of the operation panel 14 from the support unit 20. Accordingly, the stopper unit 54 also functions as a push-out mechanism.

An edge part 38g is formed on the front side of the engagement projection 38c on the top face of the rear cover 38. When the engagement projection 38c engages with the engagement hole 50d, the bent part of the front bracket 50 is positioned between the engagement projection 38c and the edge part 38g. As the inclined part 38f is pushed out by the push-out part 62b, the operation panel 14 is spaced from the support unit 20 while turning around the engaging point between the engagement projection 38c and the engagement hole 50d. During the turn, the bent part of the front bracket 50 is continuously positioned between the engagement projection 38c and the edge part 38g, hence the engaging between the engagement projection 38c and the engagement hole 50d is maintained.

The tip of the latch member 60 slides upwards on the inclined part 38f as the operation panel 14 moves rotationally. The latching rod 62c latches with the projection 38e when the operation panel 14 moves rotationally at a predefined angle. This limits the turning range of the operation panel 14, which turns around the engaging point between the engagement projection 38c and the engagement hole 50d. The stopper 62 is biased by the spring 70 to raise the projection 38e upwards. Hence, even if a user release his or her hand from the operation panel 14, the engagement both between the engagement projection 38c and the engagement hole 50d and between the projection 38e and the latching rod 62c are maintained, and the operation panel 14 is supported by the support unit 20. This prevents the operation panel 14 from falling just after the lever 60a is operated.

FIG. 12(C) is a drawing illustrating the state where the panel top face 14b is pressed from the state of FIG. 12(B). The stopper 62 turns against the biasing force created by the spring 70, and the operation panel 14 moves downwards. When the operation panel 14 moves somewhat downwards, the engaging between the engagement hole 50d and the engagement projection 38c is released. This allows the upper part of the operation panel 14 to be drawn.

FIG. 12(D) is a drawing illustrating the state where the operation panel 14 is pulled out from the state of FIG. 12(C) to the nearest side and upper side of the system. Then, the latching between the latching rod 62c and the projection 38e is also released, and the operation panel 14 is completely separated from the support unit 20.

The present invention should not be limited to each embodiment stated above. An appropriate combination of each element of the above embodiments is effective as an embodiment of the invention. Further, various modifications including design modifications, can be made with respect to the each embodiment based on the knowledge of those skilled in the art. An embodiment with such a modification should fall within the scope of the present invention. Examples of such are as follows.

According to an embodiment, a plurality of (for example, two) levers 60a are provided at a minute clearance from the panel back face 14d. When any one of the plurality of the levers 60a is pressed by a user, the hook part 60b is lifted, allowing the latching with the projection 38b to be released. This allows the levers 60a to be provided in both the driver side and the passenger side, for example.

According to another embodiment, the latching between the stopper 62 and the projection 38e can be released by pulling the operation panel 14 around the latching point between the engagement projection 38c and the engagement hole 50d from the state of FIG. 11(B). Specifically, in this embodiment, an inclined part is provided in a part of the projection 38e, where the projection 38e latches with the latching rod 62c. Hence, the engagement can be released by pulling out the lower part of the operation panel 14 with a somewhat strong force, even when the projection 38e and the latching rod 62c are latched. This allows the operation panel 14 to be easily and completely detached from the support unit 20 without pressing the operation panel 14 downwards once.

What is claimed is:

1. A panel detaching mechanism, the mechanism comprising:
a member operable by a user; and
a latch mechanism for:
latching a panel with a main body, and
releasing a latch between the panel and the main body when the member is operated by the user, the member located near a back face of the panel where the panel is latched with the main body.

2. The panel detaching mechanism of claim 1, wherein the main body includes:
a support member for latching the panel, and
a tilt mechanism for pulling out the support member when the panel is latched, whereby an outer edge portion from amongst all of the outer edge portions of the panel may be pulled out more than any other outer edge portion when the panel is latched at a predetermined standard position, and wherein the member cannot be operated by the user when the operating member is close to the main body so that the panel is latched by the support member at the standard position, and the member can be operated by the user when the support member is pulled out with the panel latched.

3. The panel detaching mechanism of claim 2, wherein the member is further located near the outer edge portion that may be pulled out more than any of outer edge portion.

4. The panel detaching mechanism of claim 3, wherein a longitudinal outer edge portion from amongst all of the outer edge portions may be pulled out more than other of the outer edge portions, the member further arranged in the vicinity of the longitudinal outer edge portion.

5. The panel detaching mechanism of claim 1, the mechanism further comprising:
a detachment guide mechanism for guiding the panel when the latching with the main body is released and the panel is detached from the main body; and
a detachment limiting mechanism for limiting movement of the panel within a predetermined range of a guide direction.

6. The panel detaching mechanism of claim 5, wherein the detachment limiting mechanism releases the limitation of movement of the panel when the panel is moved in a predefined direction different from the guide direction.

7. The panel detaching mechanism of claim 1, wherein the operating member is arranged near an outer edge so that the distance between the operating member and the opposing outside edge is within a length so that the panel can be held with one hand.

8. The panel detaching mechanism of claim 1, wherein the panel further comprises a holding part that forms a part of the outer edge whereby a user can hold the holding part when detaching the panel, and wherein the member is arranged so that the holding part is positioned between the member and the panel front face.

9. The panel detaching mechanism of claim 1, wherein a display is arranged in front of the panel.
